(19) United States
(12) Patent Application Publication
(10) Pub. No.: US 2026/0333750 A1
(43) Pub. Date: Oct. 22, 2026

(54) HIGH VOLTAGE DEVICE AND METHOD FOR FORMING THE SAME

(71) Applicant: TAIWAN SEMICONDUCTOR MANUFACTURING COMPANY LTD., HSINCHU (TW)

(72) Inventors: HUNG-CHIH TSAI, KAOHSIUNG CITY (TW); TUNG-YANG LIN, NEW TAIPEI CITY (TW); RUEY-HSIN LIU, HSINCHU CITY (TW); MING-TA LEI, HSIN-CHU CITY (TW)

(21) Appl. No.: 19/182,687

(22) Filed: Apr. 18, 2025

(51) Int. Cl. H10D 30/65; H10D 30/01; H10D 62/10; H10D 64/27

(52) U.S. Cl. CPC H10D 30/655; H10D 30/0281; H10D 62/102; H10D 62/116; H10D 62/126; H10D 64/516; H10D 64/518; H10D 64/519

(57) ABSTRACT

A high-voltage device includes a substrate, an isolation structure disposed in the substrate, a gate structure disposed over the substrate and the isolation structure, an insulating structure disposed in the gate structure, a drain region disposed on a first side of the gate structure, and source region disposed on a second side of the gate structure. The insulating structure overlaps an interface between the substrate and the isolation structure.

### BACKGROUND

Technological advances in semiconductor integrated circuit (IC) materials, design, processing, and manufacturing have enabled continual reduction in size of IC devices, where each generation has smaller and more complex circuits than the previous generation.

As semiconductor circuits composed of devices such as metal-oxide-semiconductor field-effect transistors (MOSFETs) are adapted for high-voltage applications, such as high-voltage lateral diffusion metal-oxide-semiconductor (HV LDMOS) devices, problems arise with respect to decreasing voltage performance as the downscaling continues with advanced technologies. To prevent punch-through between source and drain, or to reduce resistance of the source and drain, standard MOS fabrication process flows may be accompanied by multiple implantations with high dopant concentrations. As a result, substantial substrate leakage and voltage breakdown occur, causing reduction of device reliability.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a plan view of a high-voltage device according to aspects of the present disclosure in one or more embodiments.

FIG. 2 is a cross-sectional view of a high-voltage device according to aspects of the present disclosure in one or more embodiments.

FIG. 3 is a partially-enlarged view of a high-voltage device according to aspects of the present disclosure in one or more embodiments.

FIG. 4 is a cross-sectional view of a high-voltage device according to aspects of the present disclosure in one or more embodiments.

FIG. 5 is a partially-enlarged view of a high-voltage device according to aspects of the present disclosure in one or more embodiments.

FIG. 6A is a graph of electron density data of a high-voltage device of a comparative approach, and FIG. 6B is a graph of electron density data of a high-voltage device according to aspects of the present disclosure in one or more embodiments.

FIG. 7 is a graph illustrating a comparison of breakdown voltages of a high-voltage device of a comparative approach and a high-voltage device according to aspects of the present disclosure in one or more embodiments.

FIG. 8 is a graph illustrating a comparison of leakage currents of a high-voltage device of a comparative approach and a high-voltage device according to aspects of the present disclosure in one or more embodiments.

FIG. 9 is a flowchart representing a method for forming a semiconductor structure according to aspects of the present disclosure.

FIGS. 10A to 10K are schematic drawings of a semiconductor structure at various fabrication stages according to aspects of the present disclosure in one or more embodiments.

FIG. 11 is a plan view of a gate structure of a semiconductor structure at a fabrication stages according to aspects of the present disclosure in one or more embodiments.

FIGS. 12A to 12K are schematic drawings of a semiconductor structure at various fabrication stages according to aspects of the present disclosure in one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat references numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any references to direction or orientation are merely intended for convenience of description and are not intended in any way to limit the scope of the present disclosure. Relative terms such as “lower,” “upper,” “horizontal,” “vertical,” “above,” “below,” “up,” “down,” “top” and “bottom,” as well as derivatives thereof (e.g., “horizontally,” “downwardly,” “upwardly,” etc.), should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by references to the embodiments. Accordingly, the disclosure expressly should not be limited to such embodiments illustrating some possible non-limiting combination of features that may exist alone or in other combinations of features, the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Electric field plays an important role in design and operation of high-voltage devices. Therefore, approaches are used to help manage electric fields within these devices by reducing peak electric fields generated by gate electrodes, thereby preventing device breakdown and allowing for higher breakdown voltages. For example, field plates are important components in the high-voltage devices, enhancing performance and reliability of the high-voltage devices by strategically manipulating the electric fields generated by the gate electrode. By positioning the field plate over a channel region, the field plate helps reduce peak electric fields, enabling devices like LDMOS (laterally-diffused metal-oxide-semiconductor) transistors to achieve higher breakdown voltages.

In some comparative approaches, it is found that different portions of a high-voltage gate dielectric layer may have inconsistent thicknesses even if such portions are formed in a same operation. For example, a thickness of a portion of the gate dielectric layer over an interface between a substrate and an isolation may be less than a thickness of other portions of the gate dielectric layer over the substrate and/or over the isolation. In such approaches, electric field may be greater around a portion of the gate dielectric layer having less thickness even if field plates are present. The increased electric field around the interface between the substrate and the isolation causes the high-voltage device to exhibit a reliability issue.

The present disclosure therefore provides a high-voltage device having an insulating structure disposed within a gate electrode of the high-voltage device. In some embodiments, the insulating structure overlaps an interface between a substrate and an isolation where the gate electrode is disposed. Accordingly, an electric field near the interface, in an area where a thickness of a gate dielectric layer is less than a thickness of the gate dielectric layer in other areas, is reduced. Further, an area of maximum electric field is moved away from the interface. Accordingly, a reliability issue can be mitigated. In some embodiments, this is accomplished by adding the insulating structure into a gate structure without modifying operations and/or parameters for forming other elements of the high-voltage device, thereby providing a compatible method for forming the high-voltage device.

In some embodiments, a high-voltage device is provided. The high-voltage device can be an n-type high-voltage device, but the disclosure is not limited thereto. For example, in some alternative embodiments, the high-voltage device can be a p-type high-voltage device. In some embodiments, the high-voltage device can be as a high-voltage laterally-diffused MOS (HV LDMOS) transistor device, a high-voltage extended-drain MOS (HV EDMOS) transistor device, or any other high-voltage device.

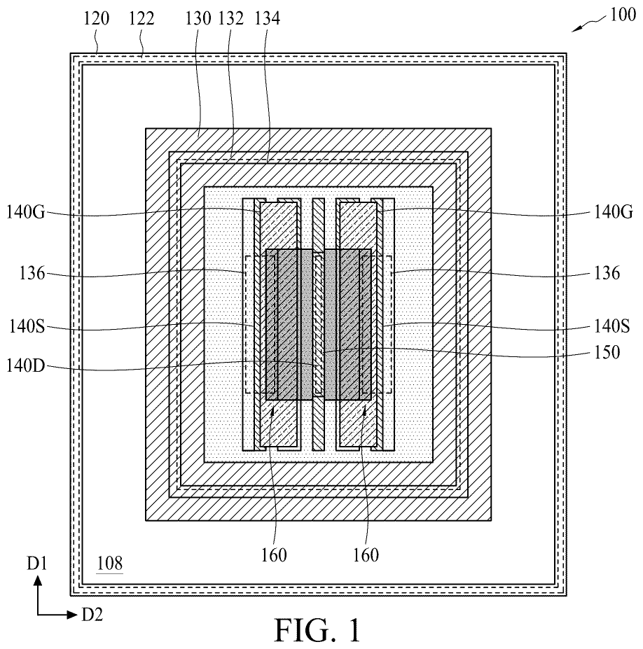

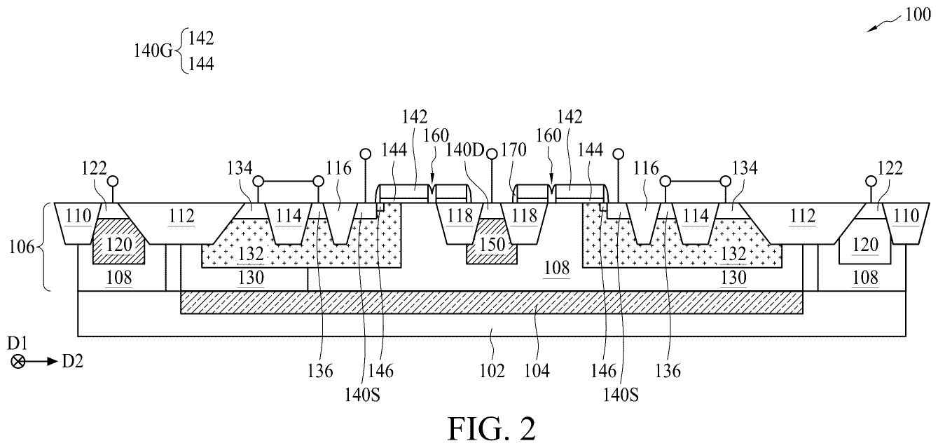

Please refer to FIGS. 1 and 2, wherein FIG. 1 is a top view of a p-type high-voltage device 100. In some embodiments, FIG. 2 is a simplified cross-sectional view of FIG. 1. In some embodiments, the high-voltage device 100 includes a substrate 102 (shown in FIG. 2). The substrate 102 can include an elementary semiconductor such as silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may be a SiGe alloy with a gradient Si—Ge feature in which the Si and Ge composition changes from one ratio at one location to another ratio at another location of the gradient SiGe feature. In another embodiment, the SiGe alloy is formed over a silicon substrate. In some embodiments, the SiGe alloy can be mechanically strained by another material in contact with the SiGe alloy. Furthermore, the substrate 102 may be a semiconductor on insulator, such as silicon on insulator (SOI). In some embodiments, the substrate 102 may have a multilayer structure, or may include a multilayer compound semiconductor structure.

The substrate 102 may include a first conductivity type. In some embodiments, the substrate 102 may include a doped epitaxial layer and/or a buried layer 104. In such embodiments, the buried layer 104 may include a second conductivity type complementary to the first conductivity type. For example, when the substrate 102 is a p-type substrate, the buried layer 104 may be an n-type buried layer. The buried layer 104 is therefore referred to as an n-type buried layer (NBL). In some embodiments, n-type dopants of the buried layer 104 include arsenic (As), phosphorus (P), other group V elements, or a combination thereof. In some embodiments, p-type dopants of the substrate 102 include boron (B), other group III elements, or a combination thereof.

In some embodiments, an epitaxial layer 106 may be disposed over the buried layer 104. In such embodiments, the epitaxial layer 106 may accommodate other elements of the high-voltage device 100. In some embodiments, the substrate 102, the buried layer 104 and the epitaxial layer 106 may be referred to as a substrate.

Referring to FIGS. 1 and 2, in some embodiments, the high-voltage device 100 includes a well region 108 including the first conductivity type. In such embodiments, the well region 108 may be referred to as a high-voltage p-well (HVPW). In some embodiments, a portion of a bottom of the well region 108 is in contact with the buried layer 104, and another portion of the bottom of the well region 108 is in contact with the substrate 102, as shown in FIG. 2.

In some embodiments, the high-voltage device 100 includes a plurality of isolation structures (i.e., shallow trench isolation (STI)) 110, 112, 114, 116 and 118 disposed in the substrate 102 (i.e., the epitaxial layer 106 over the substrate 102). It should be noted that the isolation structures 110, 112, 114, 116 and 118 are omitted from FIG. 1 in order to provide a clear view of other elements. As shown in FIG. 2, the isolation structure 110 may include a ring-shaped or frame-shaped configuration. Further, the well region 108 (i.e., the HVPW) is disposed within an area defined by the isolation structure 110. Accordingly, the well region 108 is surrounded by the isolation structure 110 from a plan view. Additionally, the isolation structures 112, 114, 116 and 118 are also disposed within the area defined by the frame-shaped isolation structure 110. In some embodiments, each of the isolation structures 112 and 114 also has a ring-shaped or frame-shaped configuration, but the disclosure is not limited thereto.

In some embodiments, the high-voltage device 100 may include another well region 120 of the first conductivity type, such as a p-well region, disposed in the substrate 102 and in the well region 108. In such embodiments, the well region 120 may be referred to as a shield p-well (SH_P). As shown in FIGS. 1 and 2, the well region 120 may have a ring-shaped or frame-shaped configuration. A bottom of the well region 120 may be in contact with the well region 108. Further, the well region 120 is disposed between the frame-shaped isolation structure 110 and the frame-shaped isolation structure 112.

In some embodiments, the high-voltage device 100 may include a doped region 122 disposed over the well region 120. The doped region 122 includes a conductivity type same as that of the well region 120, but a dopant concentration of the doped region 122 is greater than a dopant concentration of the well region 120. As shown in FIG. 1, the doped region 122 also has a ring-shaped or frame-shaped configuration, and a bottom of the doped region 122 is in contact with the well region 120. In some embodiments, the doped region 122 is disposed between the frame-shaped isolation structure 110 and the frame-shaped isolation structure 112, and is exposed through the isolation structures 110 and 112. Further, the doped region 122 is coupled to a substrate contact (not shown). In such embodiments, the doped region 122 may be referred to as a sub-contact.

In some embodiments, the high-voltage device 100 may include another well region 130 of the second conductivity type, such as an n-well region, disposed in the substrate 102 and in the well region 108. In such embodiments, the well region 130 may be referred to as a high-voltage n-well (HVNW). As shown in FIGS. 1 and 2, the well region 130 may have a ring-shaped or frame-shaped configuration. In some embodiments, the well region 130 is disposed in an area defined by the isolation structure 112. A bottom of the well region 130 may be in contact with the buried layer 104. Further, a portion of a bottom of the isolation structure 112 is in contact with the well region 130.

In some embodiments, the high-voltage device 100 may further include a well region 132 of the second conductivity type, such as n-well regions, disposed in the substrate 102. In such embodiments, the well region 132 may be referred to as shield n-wells (SH_N). As shown in FIGS. 1 and 2, the well region 132 may have a ring-shaped or frame-shaped configuration. Further, the well region 132 is disposed within an area defined by the frame-shaped isolation structure 112. As shown in FIG. 2, the well region 132 is disposed in the well region 130 and the well region 108. A first portion of a bottom of the well region 132 may be in contact with the well region 130, and a second portion of the bottom of the well region 132 may be in contact with the well region 108. Additionally, the first portion and the second portion are coupled to each other. In some embodiments, the dopant concentration of the well region 132 is greater than a dopant concentration of the well region 130.

In some embodiments, the high-voltage device 100 may include a doped region 134 and a doped region 136 disposed over the well region 132. The doped regions 134 and 136 include a conductivity type same as that of the well regions 132, but a dopant concentration of the doped regions 134 and 136 is greater than the dopant concentration of the well region 132. As shown in FIG. 1, the doped region 134 also has a ring-shaped or frame-shaped configuration, and a bottom of the doped region 134 is in contact with the well region 132. Each of the doped regions 136 has a strip configuration, and a bottom of each of the doped regions 136 is in contact with the well region 132. In some embodiments, the doped region 134 is disposed between the frame-shaped isolation structure 112 and the frame-shaped isolation structure 114, and is exposed through the isolation structures 112 and 114. The doped region 136 is disposed between the isolation structure 114 and the isolation structure 116, and is exposed through the isolation structures 114 and 116. Further, the doped regions 134 and 136 are both coupled to a bulk contact (not shown). In such embodiments, the doped regions 134 and 136 may be referred to as bulk contacts.

The high-voltage device 100 includes gate structures 140G disposed over the substrate 102. In some embodiments, the high-voltage device 100 includes two of the gate structures 140G, but the disclosure is not limited thereto. As shown in FIGS. 1 and 2, the gate structures 140G extend in the first direction D1, and are arranged in the second direction D2. In other words, the gate structures 140G and the doped regions 136 are parallel to each other. Additionally, two of the isolation structures 118 are disposed over the substrate 102. Each of the gate structures 140G covers a portion of the well region 132, a portion of the well region 108, and a portion of the respective isolation structure 118. In some embodiments, each of the gate structures 140G includes a gate conductive layer 142 and a gate dielectric layer 144 between the gate conductive layer 142 and the substrate 102. The gate conductive layer 142 can include polysilicon, silicon-germanium, and at least one metallic material including elements and compounds such as Mo, Cu, W, Ti, Ta, TiN, TaN, NiSi, CoSi, or other suitable conductive materials known in the art. In some embodiments, the gate conductive layer 142 includes a work function metal layer that provides a metal gate with an n-type work function or a p-type work function. Materials having the p-type work function materials include ruthenium, palladium, platinum, cobalt, nickel, conductive metal oxide, and other suitable materials. Materials having the n-type work function include hafnium zirconium, titanium, tantalum, aluminum, metal carbides (e.g., hafnium carbide, zirconium carbide, titanium carbide, and aluminum carbide), aluminides, and other suitable materials.

The gate dielectric layer 144 can be a single layer or a multi-layer structure. In some embodiments, the gate dielectric layer 144 is a multi-layer structure that includes an interfacial layer and a high-k dielectric layer. The interfacial layer can include dielectric material such as silicon oxide, silicon nitride, silicon oxynitride, other dielectric material, or a combination thereof. The high-k dielectric layer can include high-k dielectric material such as HfO₂, HfSiO, HfSiON, HfTaO, HfTiO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

In some embodiments, the high-voltage device 100 further includes a well region 150 of the first conductivity type, such as a p-well region, disposed in the substrate 102 and in the well region 108. In such embodiments, the well region 150 may be referred to as a shield p-well (SH_P). As shown in FIGS. 1 and 2, the well region 150 may have a strip configuration, and is disposed between the two gate structures 140G and between the two isolation structures 118. A bottom of the well region 150 may be in contact with the well region 108. In some embodiments, a dopant concentration of the well region 150 is equal to the dopant concentration of the well region 120, but the disclosure is not limited thereto.

In some embodiments, the high-voltage device 100 includes two source regions 140S and one drain region 140D of the first conductivity type. Each of the source regions 140S and the drain region 140D extends in the direction D1, and the source regions 140S and the drain region 140D are arranged in the second direction D2. Therefore, the source regions 140S, the drain region 140D, and the gate structures 140G are parallel to each other. In some embodiments, each of the source regions 140S is disposed in respective well region 132, and is separated from the doped region 136 by the isolation structure 116. A bottom of each of the source regions 140S is in contact with the respective well region 132. The drain region 140D is disposed between the two gate structures 140G and over the well region 150. A bottom of the drain region 140D is in contact with the well region 150. In some embodiments, the drain region 140D is a shared drain region; that is, the drain region 140D is shared by the two gate structures 140G. Each of the gate structures 140G is disposed between one of the source regions 140S and the shared drain region 140D.

In some embodiments, the high-voltage device 100 may include a lightly-doped region 146 disposed in the well region 134. The lightly-doped region 146 is adjacent to the source region 140S, and includes the first conductivity type. A dopant concentration of the lightly-doped region 146 is less than the dopant concentration of the source region 140S.

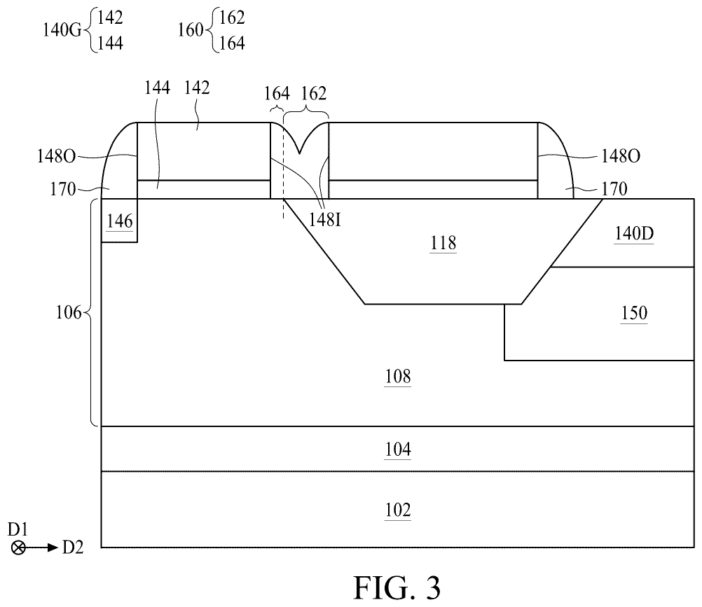

Please refer to FIG. 3, which is a partially-enlarged view of a high-voltage device in accordance with some embodiments of the present disclosure. In some embodiments, FIG. 3 is a partially-enlarged view of the high-voltage device 100 of FIGS. 1 and 2. In some embodiments, the high-voltage device 100 includes an insulating structure 160 disposed in each of the gate structures 140G. In some embodiments, the insulating structure 160 extends in the first direction D1. That is, an extending direction of the insulating structure 160 and extending directions of the gate structures 140G are parallel. In some embodiments, a width of the insulating structure 160 is less than a width of the respective gate structure 140G, and a length of the insulating structure 160 is less than a length of the respective gate structure 140G. Further, the insulating structure 160 is disposed away from boundaries of the respective gate structure 140G; therefore, the insulating structure 160 is entirely surrounded by the respective gate structure 140G, as shown in FIG. 1. Accordingly, the gate structure 140G includes an inner sidewall 148I and an outer sidewall 148O, wherein the inner sidewalls 148I laterally surround the insulating structure 160.

Still referring to FIG. 3, the insulating structure 160 overlaps an interface between the substrate 102 (i.e., the well region 108 in the substrate 102) and the isolation structure 118. Further, the insulating structure 160 is in contact with the interface between the substrate 102 (i.e., the well region 108 in the substrate 102) and the isolation structure 118. In some embodiments, the insulating structure 160 includes a first portion 162 disposed over the isolation structure 118, and a second portion 164 disposed over the substrate 102 (i.e., the well region 108 in the substrate 102). A width of the first portion 162 is equal to or greater than a width of the second portion 164. In some embodiments, the insulating structure 160 may have a concave top surface, as shown in FIGS. 2 and 3. In such embodiments, a thickness of the insulating structure 160 is equal to or less than a thickness of the respective gate structure 140G.

Each of the gate structures 140G further includes spacers 170 disposed over the outer sidewalls 148O. However, the spacers 170 are omitted from FIG. 1. The spacer 170 and the insulating structure 160 include a same material. In some embodiments, the insulating structure 160 and the spacer 170 are made of silicon nitride (SiN), silicon carbide (SiC), silicon oxide (SiO_{X}), silicon oxynitride (SiON) or any other suitable material, but the disclosure is not limited thereto.

In some embodiments, the insulating structure 160 disposed within the gate structures 140G helps to modify the electric field, such that a performance and a reliability of the high-voltage device 100 are improved. The improvement is discussed in detail below.

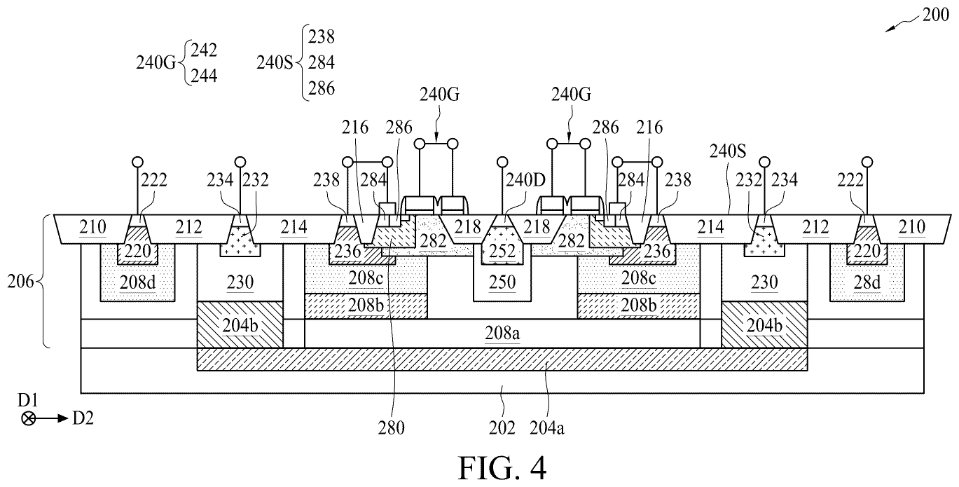

Please refer to FIG. 4, which is a cross-sectional view of an n-type high-voltage device 200 according to aspects of the present disclosure in one or more embodiments. In some embodiments, the high-voltage device 200 includes a substrate 202. A material of the substrate 202 may be similar to materials of the substrate 102, and repeated descriptions are omitted for brevity.

The substrate 202 may include a first conductivity type. For example, the substrate 202 may include a p-type substrate. In some embodiments, the substrate 202 may include a doped epitaxial layer and/or a buried layer 204a and a buried layer 204b coupled to the buried layer 204a. In such embodiments, the buried layers 204a and 204b may include a second conductivity type complementary to the first conductivity type. For example, when the substrate 202 is a p-type substrate, the buried layers 204a and 204b may be n-type buried layers. In such embodiments, the buried layer 204a may be referred to as a bottom n-type buried layer (BNBL), and the buried layer 204b may be referred to as an NBL. N-type dopants and p-type dopants used in the high-voltage device 200 may be similar to those used in the high-voltage device 100; repeated descriptions are omitted for brevity.

In some embodiments, an epitaxial layer 206 may be disposed over the buried layer 204a. In such embodiments, the epitaxial layer 206 may accommodate other elements of the high-voltage device 200. Additionally, as shown in FIG. 4, in some embodiments, the buried layer 204a may be formed under the epitaxial layer 206, while the buried layer 204b may be extended into the epitaxial layer 206. In some embodiments, the buried layer 204b may have a ring-shaped configuration or a frame-shaped configuration. A top surface of the buried layer 204b is higher than a top surface of the buried layer 204a. Accordingly, the buried layers 204a and 204b may form an U-shaped configuration in the cross-sectional view.

For example, well regions 208a and 208b are formed in the epitaxial layer 206. As shown in FIG. 4, in some embodiments, both the deep well regions 208a and 208b are disposed over the buried layer 204a, while the deep well region 208b is disposed over and coupled to the deep well region 208a. The deep well regions 208a and 208b include the first conductivity type. Therefore, the deep well regions 208a and 208b may be referred to as a deep p-well (DPW). In some embodiments, a bottom of the deep well region 208a is in contact with the buried layer 204a, but the disclosure is not limited thereto. Further, the deep well regions 208a and 208b are laterally surrounded by the ring-shaped or frame-shaped buried layer 204b. The deep well regions 208a and 208b are laterally separated from the ring-shaped or frame-shaped buried layer 204b. A top surface of the deep well region 208b is higher than a top surface of the deep well region 208a. Accordingly, the deep well regions 208a and 208b form an U-shaped configuration in the cross-sectional view. Additionally, the top surface of the deep well region 208b may be higher than or aligned (i.e., coplanar) with the top surface of the buried layer 204b, but the disclosure is not limited thereto.

In some embodiments, the high-voltage device 200 includes more well regions disposed in the epitaxial layer 206. For example, the well region 208c may be disposed in the epitaxial layer 206 and over the deep well regions 208a and 208b. Further, the well region 208c may be directly disposed over the deep well region 208b. In other words, the well region 208c overlaps the deep well region 208b. In some embodiments, the well region 208c is laterally surrounded by the buried layer 204b and separated from the buried layer 204b, as shown in FIG. 4. In some embodiments, the well region 208d is disposed in the epitaxial layer 206. The well region 208d may have a ring-shaped or frame-shaped configuration. Further, the well region 208d laterally surrounds the bottom buried layer 204a, the buried layer 204b and the well region 208c. In some embodiments, the well region 208d may be separated from the buried layer 204b, but the disclosure is not limited thereto. In some embodiments, a depth of the well region 208d may be similar to a depth of the well region 208c, but the disclosure is not limited thereto. In some embodiments, a bottom of the well region 208c is in contact with the deep well region 208b, while a bottom of the well region 208d is in contact with the substrate 202 or the epitaxial layer 206. In some embodiments, each of the well regions 208c and 208d includes the first conductivity type. In some embodiments, the well regions 208c and 208d are high-voltage p-type wells (HVPW), but the disclosure is not limited thereto. In some embodiments, a dopant concentration of the well region 208c is equal to a dopant concentration of the well region 208d, but the disclosure is not limited thereto.

In some embodiments, the high-voltage device 200 includes a plurality of isolation structures 210, 212, 214, 216 and 218 disposed in the substrate 202 (i.e., the epitaxial layer 206 over the substrate 202). In some embodiments, the isolation structure 210 may include a ring-shaped or frame-shaped configuration. In some embodiments, the isolation structures 212 and 214 also have ring-shaped or frame-shaped configurations. Further, the well region 208d is disposed between the isolation structures 210 and 212, and the well region 208c disposed within an area defined by the isolation structure 214. Additionally, the isolation structures 212, 214, 216 and 218 are also disposed within the area defined by the frame-shaped isolation structure 210.

In some embodiments, the high-voltage device 200 may include another well region 220 of the first conductivity type, such as a p-well region, disposed in the substrate 202 and in the well region 208d. In such embodiments, the well region 220 may be referred to as a shield p-well (SH_P). In some embodiments, the well region 220 may have a ring-shaped or frame-shaped configuration. A bottom of the well region 220 may be in contact with the well region 208d. Further, the well region 220 is disposed between the frame-shaped isolation structure 210 and the frame-shaped isolation structure 212.

In some embodiments, the high-voltage device 200 may include a doped region 222 disposed over the well region 220. The doped region 222 includes a conductivity type same as that of the well region 220, but a dopant concentration of the doped region 222 is greater than a dopant concentration of the well region 220. The doped region 222 also has a ring-shaped or frame-shaped configuration, and a bottom of the doped region 222 is in contact with the well region 220. In some embodiments, the doped region 222 is disposed between the frame-shaped isolation structure 210 and the frame-shaped isolation structure 212, and is exposed through the isolation structures 210 and 212. Further, the doped region 222 is coupled to a substrate contact (not shown). In such embodiments, the doped region 222 may be referred to as a sub-contact.

In some embodiments, the high-voltage device 200 may include another well region 230 of the second conductivity type, such as an n-well region, disposed in the substrate 202, and over the buried layer 204b. In such embodiments, the well region 230 may be referred to as a high-voltage n-well (HVNW). In some embodiments, the well region 230 may have a ring-shaped or a frame-shaped configuration. In some embodiments, the well region 230 is disposed between the frame-shaped isolation structure 212 and the frame-shaped isolation structure 214. A depth of the well region 230 may be less than a depth of the buried layer 204b. In some embodiments, a bottom of the well region 230 may be in contact with the buried layer 204b. Additionally, the well region 230 is separated from the well regions 208c and 208d, but the disclosure is not limited thereto.

In some embodiments, the high-voltage device 200 may include another well region 232 disposed over the well region 230. The well region 232 includes a conductivity type same as that of the well region 230, but a dopant concentration of the well region 232 is greater than a dopant concentration of the well region 230. In such embodiments, the well region 232 may be referred to as a shield n-well (SH_N). In some embodiments, the well region 232 may have a ring-shaped or frame-shaped configuration. In some embodiments, the well region 232 is disposed between the frame-shaped isolation structure 212 and the frame-shaped isolation structure 214. A depth of the well region 232 may be less than a depth of the well region 230. In some embodiments, a bottom of the well region 232 may be in contact with the well region 230.

In some embodiments, the high-voltage device 200 may further include a doped region 234 disposed over the well region 232. The doped region 234 includes a conductivity type same as that of the well region 232, but a dopant concentration of the doped region 234 is greater than the dopant concentration of the well region 232. In some embodiments, the doped region 234 also has a ring-shaped or frame-shaped configuration, and a bottom of the doped region 234 is in contact with the well region 232. In some embodiments, the doped region 234 is disposed between the frame-shaped isolation structure 212 and the frame-shaped isolation structure 214, and is exposed through the isolation structures 212 and 214.

In some embodiments, the high-voltage device 200 may include another well region 236 of the first conductivity type, such as a p-well region, disposed in the substrate 202 and in the well region 208c. In such embodiments, the well region 236 may be referred to as a shield p-well (SH_P). A bottom of the well region 236 may be in contact with the well region 208c. In some embodiments, a dopant concentration of the well region 236 is greater than the dopant concentration of the well region 208c.

In some embodiments, the high-voltage device 200 may further include a doped region 238 disposed over the well region 236. The doped region 238 includes a conductivity type same as that of the well region 236, but a dopant concentration of the doped region 238 is greater than the dopant concentration of the well region 236. In some embodiments, the doped region 238 is disposed between the isolation structure 214 and the isolation structure 216, and is exposed through the isolation structures 214 and 216.

In some embodiments, the high-voltage device 200 further includes more doped regions, such as, for example, a high-voltage p-type implanted (HVPB) region 280 and a high-voltage n-type lightly-doped (HVNDD) region 282. Further, a doped region 284 of the first conductivity type and a doped region 286 of the second conductivity type are formed in the high-voltage p-type implanted region 280. In some embodiments, the doped regions 284 and 286 are separated from the high-voltage n-type lightly-doped region 282 by the high-voltage p-type implanted region 280. In some embodiments, the doped regions 238, 284 and 286 are electrically connected, and the doped regions 238, 284 and 286 all serve as a butted source region 240S.

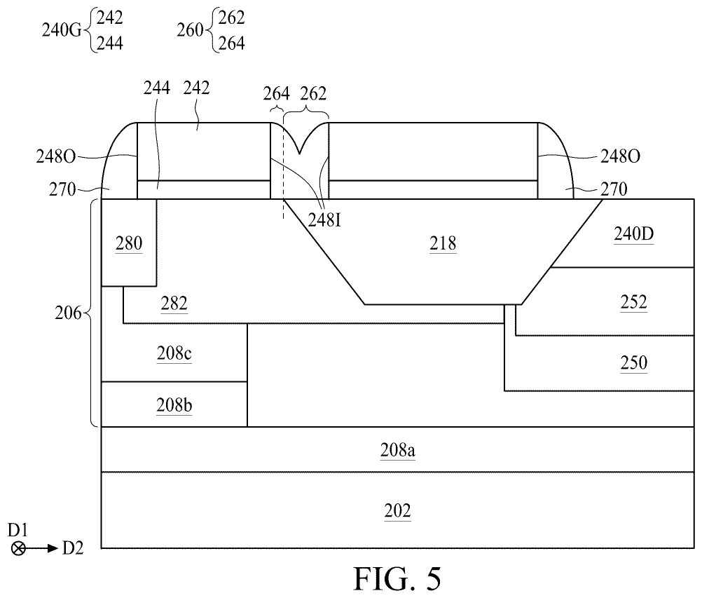

The high-voltage device 200 includes gate structures 240G disposed over the substrate 202. In some embodiments, there are two gate structures 240G in the high-voltage device 200, but the disclosure is not limited thereto. As shown in FIG. 4, the gate structures 240G extend in the direction D1. Further, each of the gate structures 240G covers a portion of the doped region 280, a portion of the doped region 282, and a portion of the isolation structure 218. In some embodiments, each of the gate structures 240G includes a gate conductive layer 242 and a gate dielectric layer 244 between the gate conductive layer 242 and the substrate 202 (both shown in FIG. 5). A material of the gate conductive layer 242 may be same as the materials of the gate conductive layer 142, and a material of the gate dielectric layer 244 may be same as the materials of the gate dielectric layer 144, and repeated descriptions are omitted.

In some embodiments, the high-voltage device 200 includes another well region 250 of the second conductivity type, such as an n-well region, disposed in the substrate 202 or the epitaxial layer 206. In such embodiments, the well region 250 may be referred to as a high-voltage n-well (HVNW). Further, the well region 250 is disposed between the two gate structures 240G. A depth of the well region 250 may be less than a thickness of the epitaxial layer 206, but the disclosure is not limited thereto. In some embodiments, the well region 250 may be separated from the deep well regions 208a and 208b, and separated from the well region 208c, but the disclosure is not limited thereto.

In some embodiments, the high-voltage device 200 may include another well region 252 disposed over the well region 250, and between the two gate structures 240G. The well region 252 includes a conductivity type same as that of the well region 250, but a dopant concentration of the well region 252 is greater than a dopant concentration of the well region 250. In such embodiments, the well region 252 may be referred to as a shield n-well (SH_N). A depth of the well region 252 may be less than a depth of the well region 250.

In some embodiments, the high-voltage device 200 includes two butted source regions 240S and one drain region 240D. In some embodiments, each of the butted source regions 240S and the drain region 240D extends in the first direction D1, and the butted source regions 240S and the drain region 240D are arranged in the second direction D2. Therefore, the butted source regions 240S, the drain region 240D, and the gate structures 240G are parallel to each other. The drain region 240D is disposed between the two gate structures 240G, and over the well region 252. A bottom of the drain region 240D is in contact with the well region 252. In some embodiments, the drain region 240D is a shared drain region; that is, the drain region 240D is shared by the two gate structures 240G. Each of the gate structures 240G is disposed between one of the butted source region 240S and the shared drain region 240D.

Please refer to FIGS. 4 and 5, wherein FIG. 5 is a partially-enlarged view of a high-voltage device in accordance with some embodiments of the present disclosure. In some embodiments, FIG. 5 is a partially-enlarged view of the high-voltage device 200 of FIG. 4. In some embodiments, the high-voltage device 200 includes an insulating structure 260 disposed in each of the gate structures 240G. In some embodiments, the insulating structure 260 extends in the first direction D1. That is, an extending direction of the insulating structure 260 and extending directions of the gate structures 240G are parallel. In some embodiments, a width of the insulating structure 260 is less than a width of the respective gate structure 240G, and a length of the insulating structure 260 is less than a length of the respective gate structure 240G. Further, the insulating structure 260 is disposed away from boundaries of the respective gate structure 240G; therefore, the insulating structure 260 is entirely surrounded by the respective gate structure 240G, in a configuration similar to that shown in FIG. 1. Accordingly, the gate structure 240G includes an inner sidewall 248I and an outer sidewall 248O, wherein the inner sidewall 248I laterally surrounds the insulating structure 260.

Still referring to FIG. 5, the insulating structure 260 overlaps an interface between the substrate 202 (i.e., the well region 282 in the substrate 202) and the isolation structure 218. Further, the insulating structure 260 is in contact with the interface between the substrate 202 (i.e., the well region 282 in the substrate 202) and the isolation structure 218. In some embodiments, the insulating structure 260 includes a first portion 262 disposed over the isolation structure 218, and a second portion 264 disposed over the substrate 202 (i.e., the well region 282 in the substrate 202). A width of the first portion 262 is equal to or greater than a width of the second portion 264. In some embodiments, the insulating structure 260 may have a concave top surface, as shown in FIGS. 4 and 5. In such embodiments, a thickness of the insulating structure 260 is equal to or less than a thickness of the respective gate structure 240G.

Each of the gate structures 240G further includes spacers 270 disposed over the outer sidewalls 248O. The spacer 270 and the insulating structure 260 include a same material. The material of the insulating structure 260 and the spacer 270 may be similar to those of the insulating structure 160 and the spacer 170, and repeated descriptions are omitted.

In some embodiments, the insulating structure 260 disposed within the gate structure 240G helps to modify the electric field, such that a performance and reliability of the high-voltage device 200 are improved.

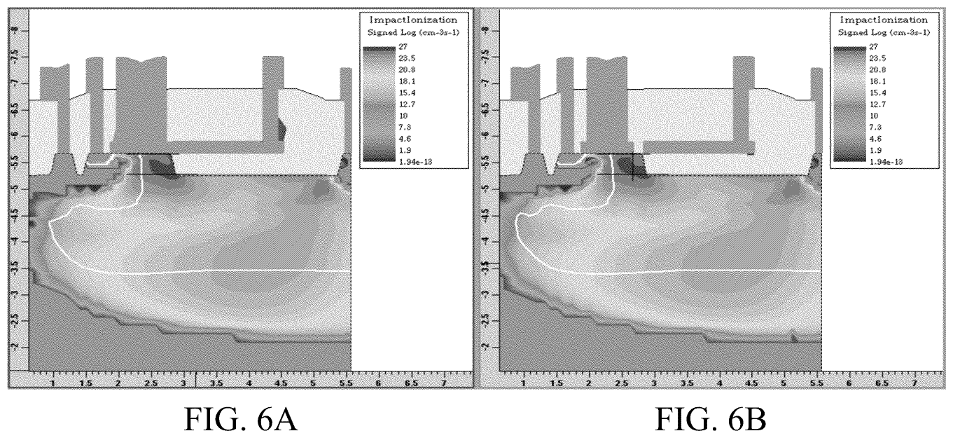

Please refer to FIGS. 6A and 6B, wherein FIG. 6A is a graph of electron density data of a high-voltage device of a comparative approach, and FIG. 6B is a graph of electron density data of a high-voltage device according to aspects of the present disclosure in one or more embodiments. FIGS. 6A and 6B may be electron density graphs from a simulation prepared using device simulation software for an IC device structure. Comparing the graphs presented in FIGS. 6A and 6B reveals that a reduction in the electron density is achieved at the interface between the isolation structures 118/218 and the substrates 102/202 (i.e., well regions 108/282). Further, an area of the maximum electron density is moved away from the interface between the isolation structures 118/218 and the substrates 102/202 (i.e., well regions 108/282). Both results tend to improve a high-voltage performance of an IC device, for example with respect to leakage current performance. Device simulation software includes, for example, Sentaurus Device, a multidimensional (1D/2D/3D) device simulator, or Taurus Medici, a 2-dimensional device simulator, both of which are useful for modeling electrical, thermal and/or optical characteristics of a wide variety of semiconductor devices.

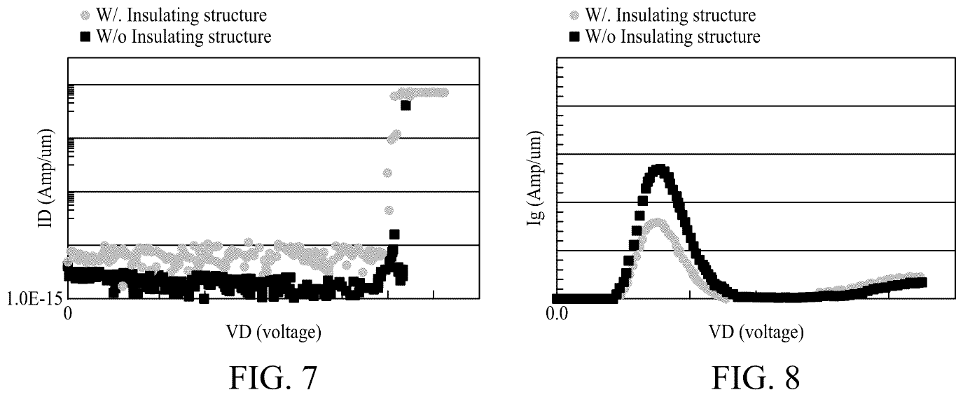

Please refer to FIGS. 7 and 8, wherein FIG. 7 is a graph illustrating a comparison of breakdown voltages of a high-voltage device of a comparative approach and a high-voltage device according to aspects of the present disclosure in one or more embodiments, and FIG. 8 is a graph illustrating a comparison of leakage currents of a high-voltage device of a comparative approach and a high-voltage device according to aspects of the present disclosure in one or more embodiments. As shown in FIG. 7, the breakdown voltages of the high-voltage devices 100 and 200 are improved when compared to those of the comparative approaches. As shown in FIG. 8, leakage currents of the high-voltage devices 100 and 200 are reduced when compared to those of the comparative approaches. It is concluded that the device performance is improved. Such improvements are achieved because electron densities at the interface between the isolation structures 118/218 and the substrate 102/202 or between the isolation structures 118/218 and the well regions 108/282 are reduced.

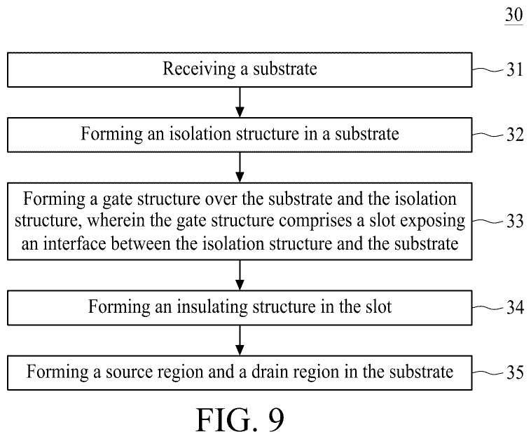

FIG. 9 is a flowchart representing a method for forming a high-voltage device 30 according to aspects of the present disclosure. The method 30 includes a number of operations (31, 32, 33, 34 and 35). The method 30 will be further described according to one or more embodiments. It should be noted that the operations of the method 30 may be rearranged or otherwise modified within the scope of the various aspects. It should further be noted that additional processes may be provided before, during, and after the method 30, and that some other processes may be only briefly described herein. Thus, other implementations are possible within the scope of the various aspects described herein.

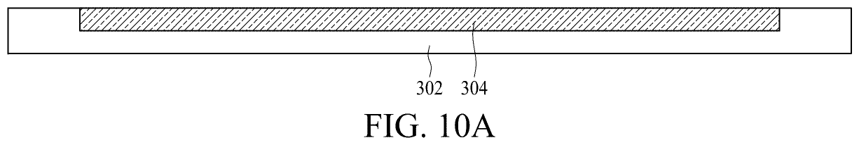

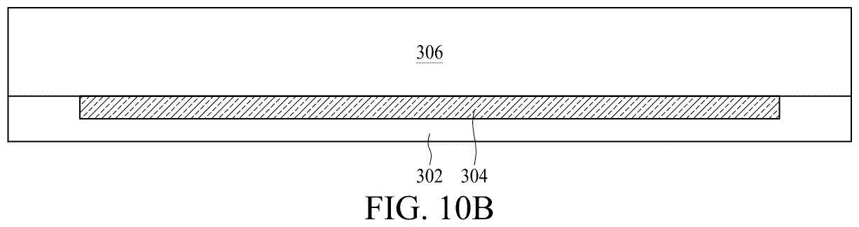

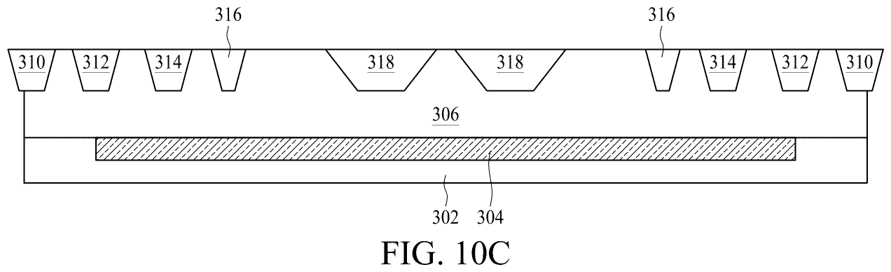

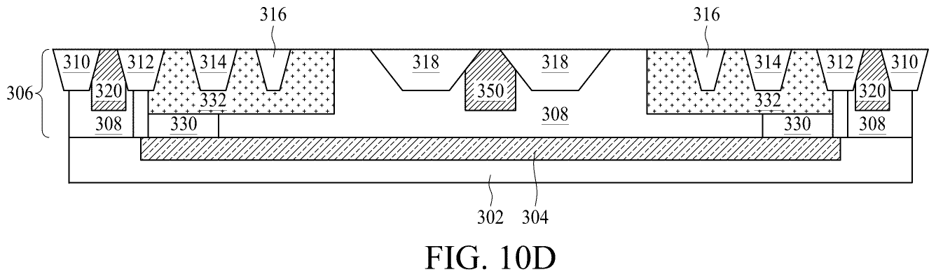

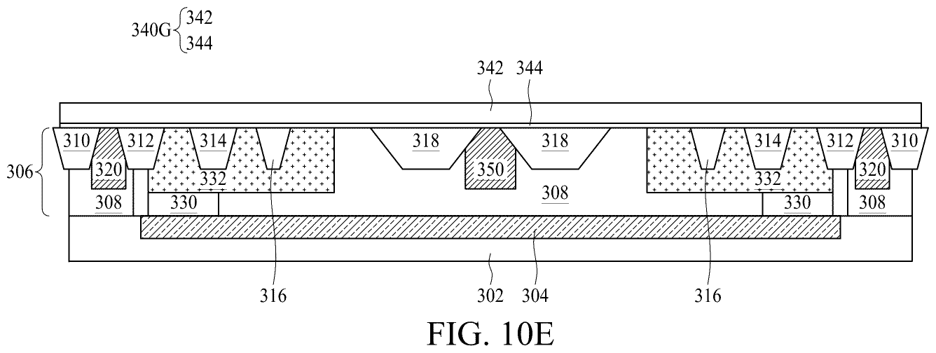

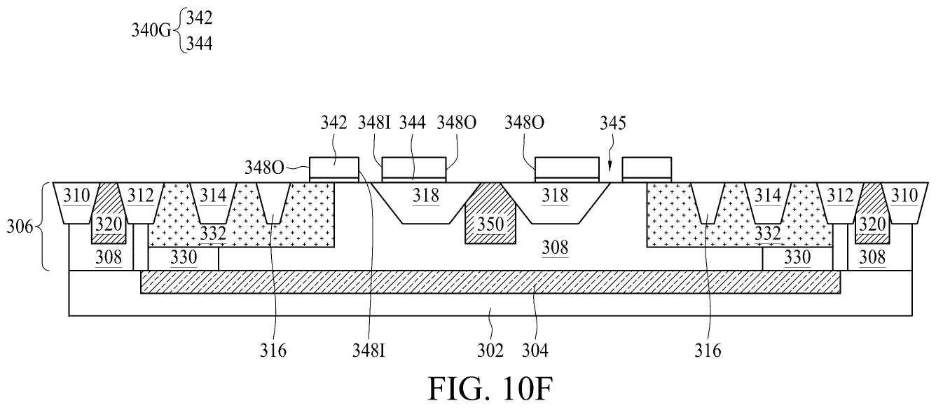

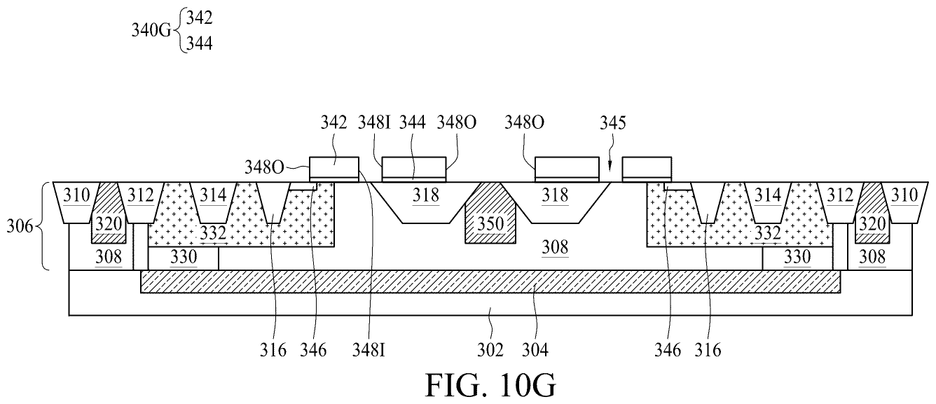

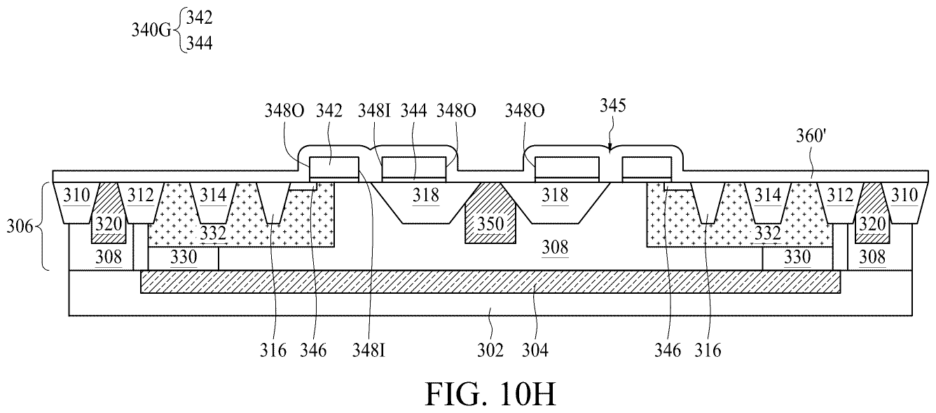

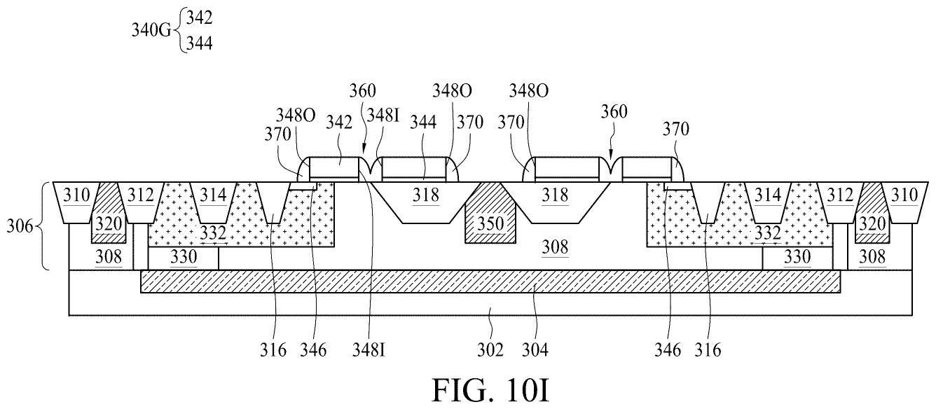

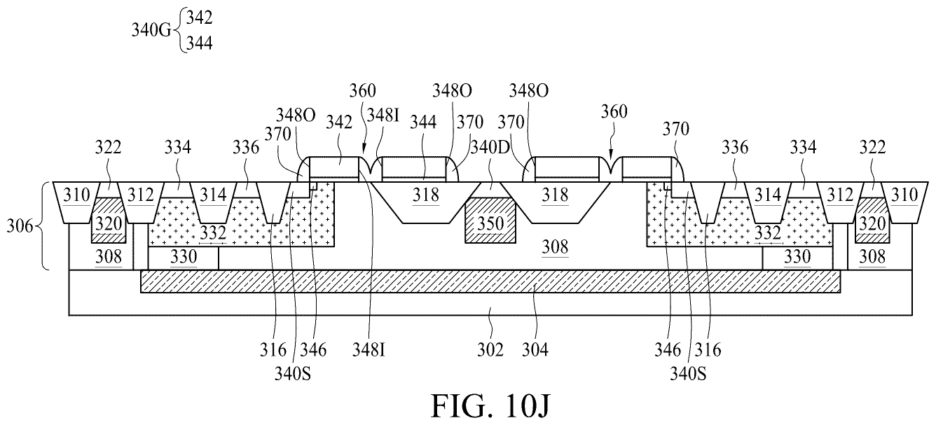

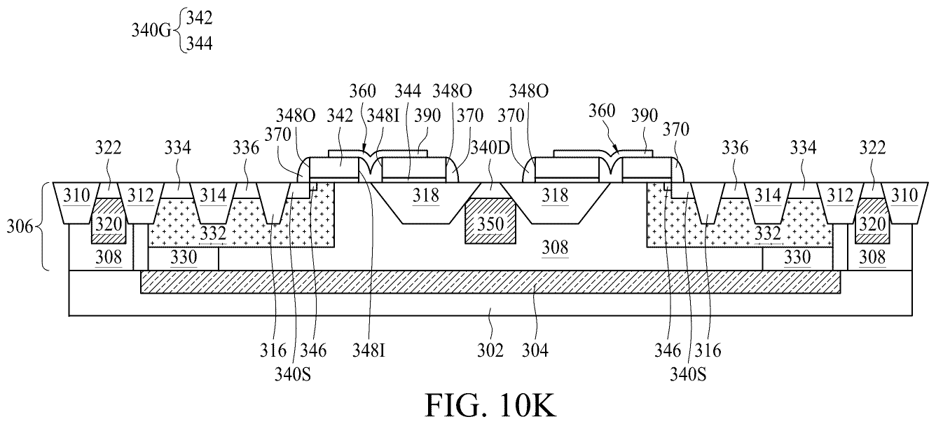

Please refer to FIGS. 10A to 10K, which are schematic drawings illustrating a semiconductor structure at various fabrication stages according to aspects of the present disclosure in one or more embodiments. It should be noted that same elements in FIGS. 1 to 3 and FIGS. 10A to 10K may include same materials, and repeated descriptions of such details are omitted for brevity.

Referring to FIG. 10A, in some embodiments, in operation 31, a substrate 302 is received. The substrate 302 may include materials same as those of the substrate 102; therefore, such details are omitted. The substrate 302 may be a semiconductor substrate of a first conductivity type. In some embodiments, operation 31 may include further operations. For example, a buried layer 304 is formed in the substrate 302. The buried layer 304 may include a second conductivity type. The first conductivity type and the second conductivity type are complementary to each other. In some embodiments, the first conductivity type is a p type, and the second conductivity type is an n type. As shown in FIG. 10A, a bottom and sides of the buried layer 304 may be respectively in contact with the substrate 302.

Referring to FIG. 10B, in some embodiments, an epitaxial layer 306 is formed over the substrate 302. The epitaxial layer 306 may be formed by vapor phase epitaxy (VPE), molecular beam epitaxy (MBE), atomic layer deposition (ALD) or any other suitable method. In some embodiments, the substrate 302, the buried layer 304 and the epitaxial layer 306 can be referred to as single substrate.

Referring to FIG. 10C, in operation 32, an isolation structure 318 is formed in the substrate 302. In some embodiments, more than one isolation structure 318 can be formed in the substrate 302 and the epitaxial layer 306. For example, isolation structures 310, 312, 314 and 316 are formed, as shown in FIG. 10C. In some embodiments, an arrangement of the isolation structures 310, 312, 314, 316 and 318 may be similar to that of the isolation structures 110, 112, 114, 116 and 118, but the disclosure is not limited thereto. It should be understood that the arrangement of the isolation structures 310, 312, 314, 316 and 318 can be modified according to various product designs.

Referring to FIG. 10D, in some embodiments, well regions may be formed in the substrate 302 and/or the epitaxial layer 306. For example, well regions 308, 320, 330, 332 and 350 are formed. In some embodiments, the well regions 308, 320, 330 and 332 may have ring-shaped or frame-shaped configurations, but the disclosure is not limited thereto. Formations of each of the well regions 308, 320, 330, 332 and 350 may include forming a patterned photoresist (not shown) over the substrate 302, and performing doping with the patterned photoresist serving as a mask for ion implantation. The patterned photoresist can be removed after the ion implantation or after the respective formation of the well regions 320, 330, 332 and 350. In some embodiments, a production order of the well regions 308, 320, 330, 332 and 350 can be: the well region 330 is formed, the well region 308 is then formed, the well region 332 is then formed, and the well regions 320 and 350 are formed. However, the production order for forming the well regions 308, 320, 330, 332 and 350 may be modified according to various process designs; therefore, details are omitted for brevity.

In some embodiments, the well region 308 may be a well region of the first conductivity type, and thus the well region 308 is referred to as an HVPW. The well regions 320 and 350 are well regions of the first conductivity type, and thus the well region 320 is referred to as an SH_P. In some embodiments, the well region 330 is a well region of the second conductivity type, and thus is referred to as an HVNW. In some the well region 332 is a well region of the second conductivity type, and thus is referred to as an SH_N. The well region 350 is disposed between the two isolation structures 318, and the well region 332 surrounds the isolation structure 312. Additionally, the well region 350 is separated from the well region 332. It should be noted that arrangements of the well regions 308, 320, 330, 332 and 350 are not limited to those described in the disclosure, and the arrangements may be modified according to various product designs. Additionally, other well regions may be formed according to various product designs; repeated descriptions are omitted for brevity.

In some embodiments, in operation 33, a gate structure is formed over the substrate 302 and the isolation structure 318. In some embodiments, operation 33 includes further operations. For example, referring to FIG. 10E, a dielectric layer 344 and a semiconductor layer 342 are sequentially formed over the substrate 302. A material of the semiconductor layer 342 may be similar to those of the gate conductive layers 142 and 242, and a material of the dielectric layer 344 may be similar to those of the gate dielectric layers 144 and 244; repeated descriptions are omitted for brevity.

Referring to FIG. 10F, the semiconductor layer 342 and the dielectric layer 344 are patterned to form the gate structure 340G. In some embodiments, more than one gate structure 340G may be formed. For example, in some embodiments, two gate structures 340G are formed over the substrate 302. In some embodiments, each of the gate structures 340G overlaps a portion of the well region 332, a portion of the substrate 302 (i.e., the epitaxial layer 306 and/or the well region 308), and a portion of isolation structure 318. Additionally, the two gate structures 340G are formed on two sides of the well region 350.

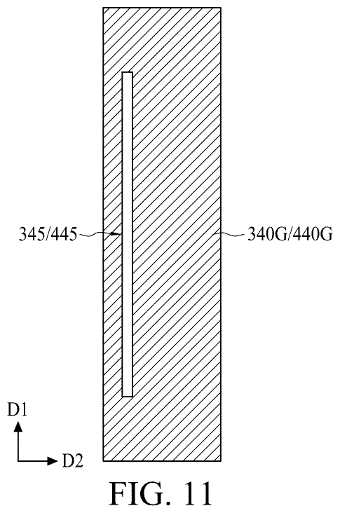

Referring to FIG. 11, which is a plan view of the gate structure 340G at a fabrication stage according to aspects of the present disclosure in one or more embodiments, in some embodiments a slot 345 is formed in each of the gate structures 340G using a same patterning operation. That is, the gate structures 340G and the slot 345 are simultaneously formed. A length of the slot 345 is less than a length of the respective gate structure 340G, and a width of the slot 345 is less than a width of the respective gate structure 340G. Further, the slot 345 is formed away from boundaries of the gate structure 340G. An extending direction of the slot 345 is parallel to an extending direction of the respective gate structure 340G. In some embodiments, an interface between the isolation structure 318 and the substrate 302 (i.e., the well region 308) is exposed though the slot 345. Further, a sidewall of the semiconductor layer 342 and a sidewall of the dielectric layer 344 are exposed through the respective slot 345. In some embodiments, each of the gate structures 340G has an inner sidewall 348I and an outer sidewall 348O, wherein the inner sidewall 348I is exposed through the respective slot 345.

In some embodiments, more or fewer well regions may be formed prior to the forming of the gate structure 340G and the slot 345, according to various product designs.

Referring to FIG. 10G, in some embodiments, further operations may be performed. For example, lightly-doped regions 346 may be formed after the formation of the gate structures 340G and the slots 345. In some embodiments, the lightly-doped regions 346 have the first conductive type, and thus are referred to as p-LDDs. As shown in FIG. 10G, the lightly-doped regions 346 may be formed in the well region 332 and abut the outer sidewall 348O of each gate structure 340G. In some embodiments, a bottom and a portion of a sidewall of each lightly-doped region 346 are in contact with the well region 332, while another portion of the sidewall of each lightly-doped region 346 is in contact with the isolation structure 316.

In some embodiments, in operation 34, an insulating structure is formed in the slot 345. In some embodiments, operation 34 includes further operations. For example, referring to FIG. 10H, an insulating material 360′ is formed over the substrate 302. The insulating material 360′ may be same as those used to form the abovementioned insulating structures 160/260; therefore, repeated descriptions are omitted. As shown in FIG. 10H, the substrate 302 is covered by the insulating material 360′, and the slot 345 is filled with the insulating material 360′.

Referring to FIG. 10I, portions of the insulating material 360′ are removed to form the insulating structure 360 in each of the gate structures 340G. In some embodiments, the removal of the portions of the insulating material 360′ may include etch-back operations, but the disclosure is not limited thereto. As shown in FIG. 10I, the insulating structure 360 is in contact with the inner sidewalls 348I of the respective gate structure 340G. That is, the gate structure 340G laterally surrounds the respective insulating structure 360. The insulating structure 360 overlaps and is in contact with the interface between the isolation structure 318 and the substrate 302 (i.e., the well region 308). In some embodiments, a portion of the insulating structure 360 is formed over the isolation structure 318, and another portion of the insulating structure 360 is formed over the substrate 302 (i.e., the well region 308 or the epitaxial layer 306). In some embodiments, a width of the portion of the insulating structure 360 over the isolation structure 318 is equal to or greater than a width of the portion of the insulating structure 360 over the well region 308, but the disclosure is not limited thereto. Relationships between the isolation structure 318, the well region 308 and the insulating structure 360 may be similar to those described above, and repeated descriptions are omitted.

In some embodiments, a spacer 370 is formed simultaneously with the forming of the insulating structure 360. As shown in FIG. 10I, the spacers 370 are formed over the outer sidewalls 348O of each of the gate structures 340G. The spacers 370 and the insulating structure 360 include same materials.

Referring to FIG. 10J, in operation 35, a source region 340S and a drain region 340D are formed. In some embodiments, when a common-drain approach or a shared-drain approach is adopted, drain region 340D is disposed between the two gate structures 340G, and two source regions 340S are formed. The source regions 340S and the drain region 340D are formed at opposite sides of each gate structure 340G, as shown in FIG. 10J. In some alternative embodiments, when a common-source or a shared-source approach is adopted, one source region is disposed between the two gate structures 340G, and two drain regions are formed. In some embodiments, the source regions 340S and the drain region 340D have the first conductivity type. As shown in FIG. 10J, each of the source region 340S is formed in the well region 332, and the drain region 340D is formed in the well region 350. A dopant concentration of the drain region 340D is same as dopant concentrations of the source regions 340S. Further, the dopant concentration of the drain region 340D is greater than a dopant concentration of the well region 350.

In some embodiments, other doped regions may be formed prior to or after the forming of the source regions 340S and the drain region 340D. For example, doped regions 334 and 336 of the second conductivity type are formed in the well region 332. In some embodiments, the doped region 334 and 336 may be formed prior to the forming of the source regions 340S and the drain region 340D, but the disclosure is not limited thereto. The doped region 336 is separated from the source region 340S by the isolation structure 316, and is separated from the doped region 334 by the isolation structure 314. A dopant concentration of each of the doped regions 334 and 336 is greater than a dopant concentration of the well region 332. In some embodiments, the doped regions 334 and 336 are coupled to a bulk contact.

In some embodiments, still other doped regions may be formed prior to or after the forming of the source regions 340S and the drain region 340D. For example, a doped region 322 of the first conductivity type is formed over the well region 320. In some embodiments, the doped region 322 may be formed simultaneously with the source regions 340S and the drain region 340D, but the disclosure is not limited thereto. The doped region 322 is formed between the isolation structures 310 and 312. Further, the doped region 322 is separated from the doped region 334 by the isolation structure 312. A dopant concentration of the doped region 322 is greater than a dopant concentration of the well region 320. In some embodiments, the doped region 322 is coupled to a sub-contact.

It should be noted that in some embodiments, more or fewer doped regions may be formed according to various product designs. Such doped regions may be formed after the forming of the insulating structure 360 and the spacer 370.

Referring to FIG. 10K, in some embodiments, after the forming of the doped regions, a dielectric layer 390, such as a resist protection oxide (RPO) layer 390 is formed over each of the insulating structures 360 and a portion of the respective gate structure 340G. In some embodiments, the RPO layer 390 includes a single layer. In other embodiments, the RPO layer 390 includes multiple layers. In some embodiments, the RPO layer 390 may include oxide material, such as SiO₂ or any suitable oxide. The RPO layer 390 may be deposited prior to a formation of a silicide structure. A portion of the intermediate device covered by the RPO layer 390 may be protected from siliciding by the RPO layer during such operation.

It should be noted that FIGS. 10A to 10K illustrates exemplary operations for forming a p-type high-voltage device. However, those skilled in the art can understand that the method 30 is not limited to the forming of a p-type voltage device, and that the method 30 can also be applied to formation of an n-type high-voltage device, as subsequently described. Accordingly, the method 30 provided by the present disclosure is compatible to processes for forming various high-voltage devices.

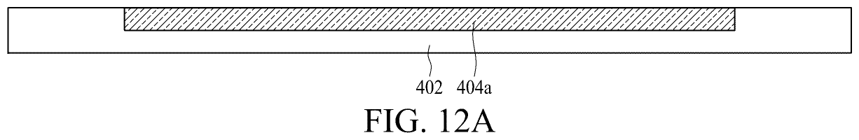

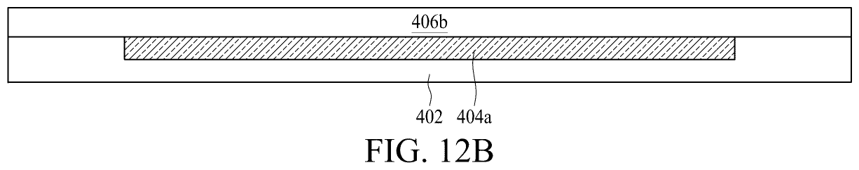

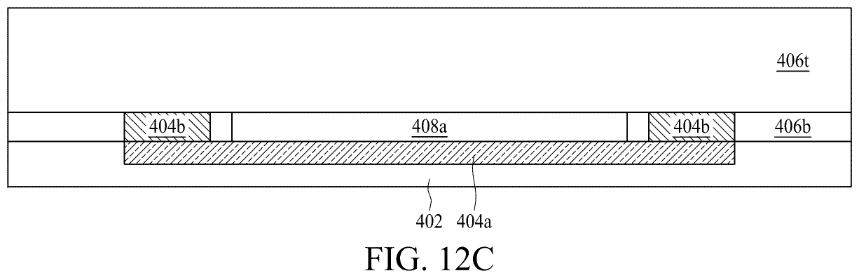

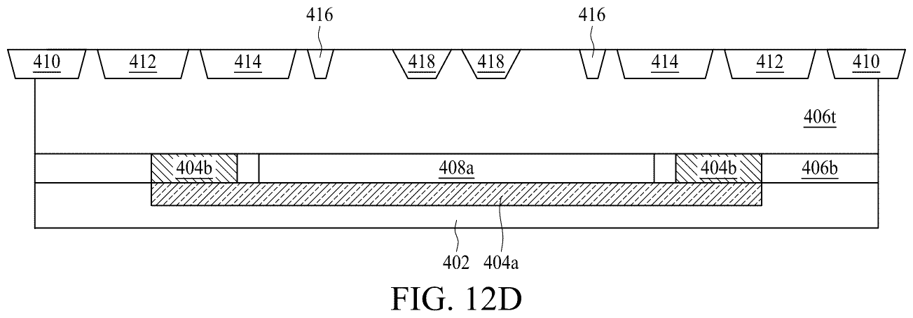

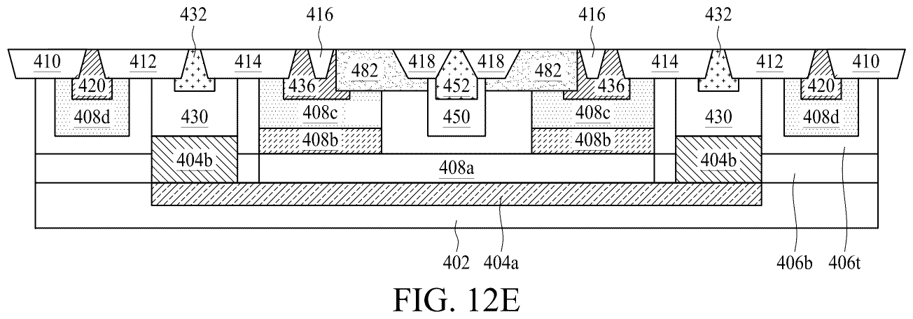

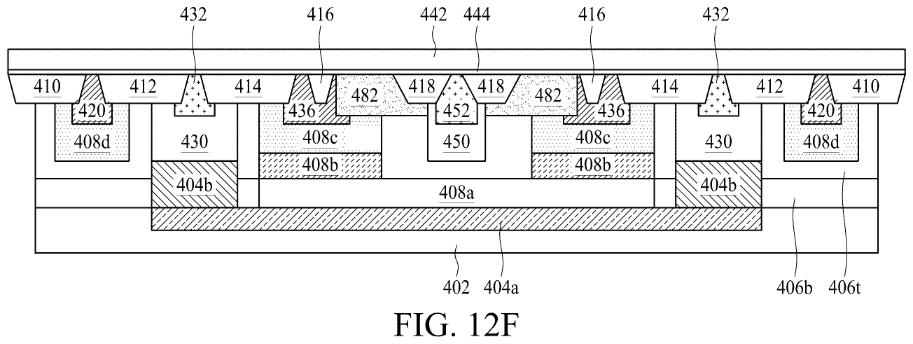

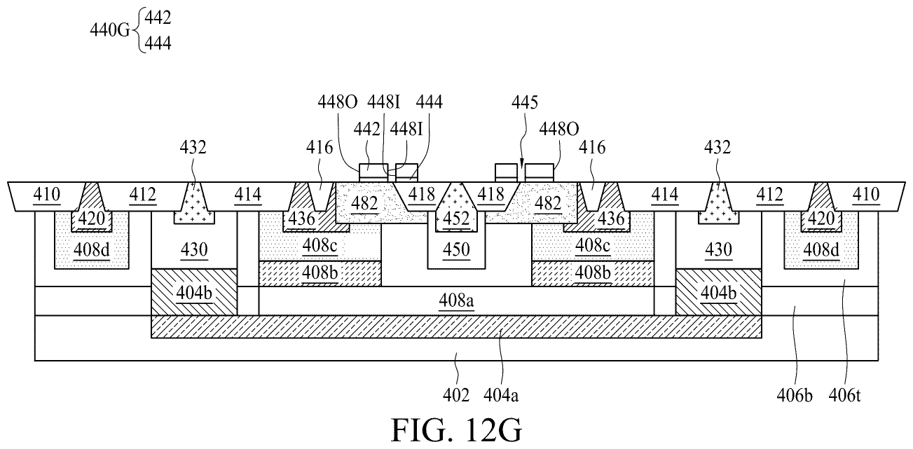

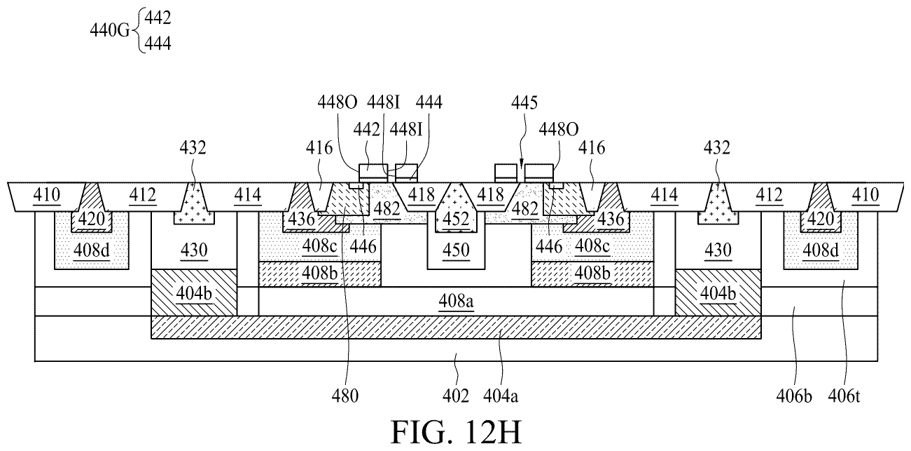

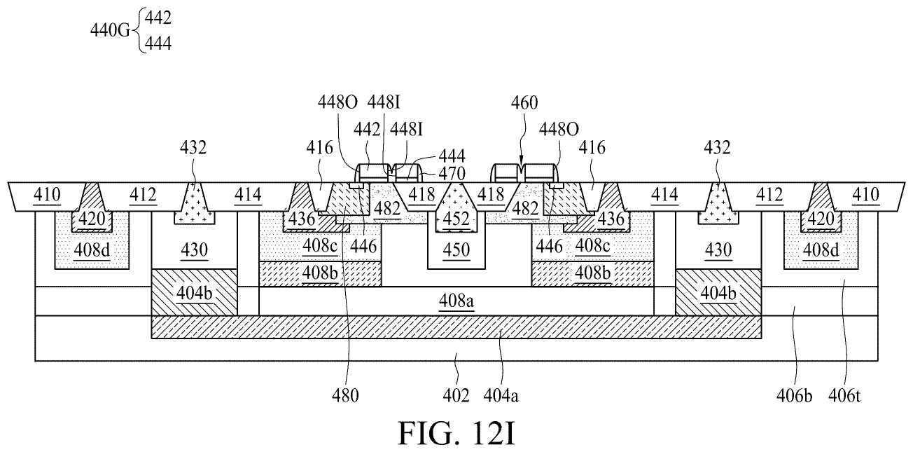

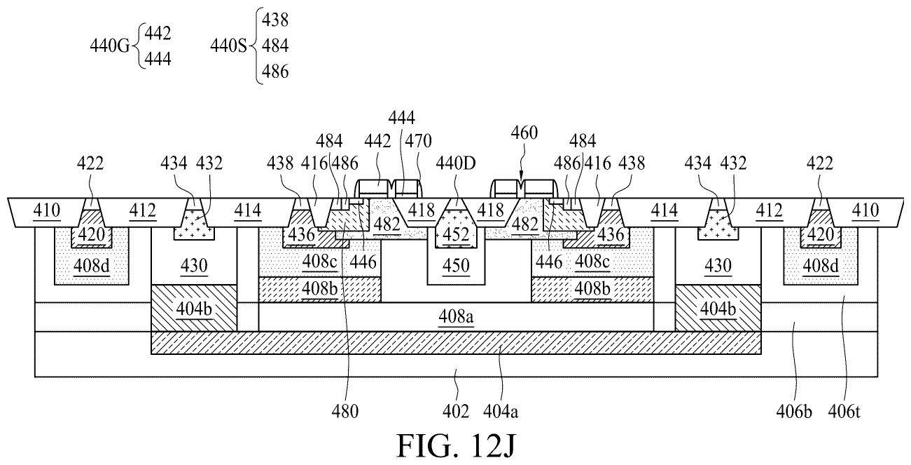

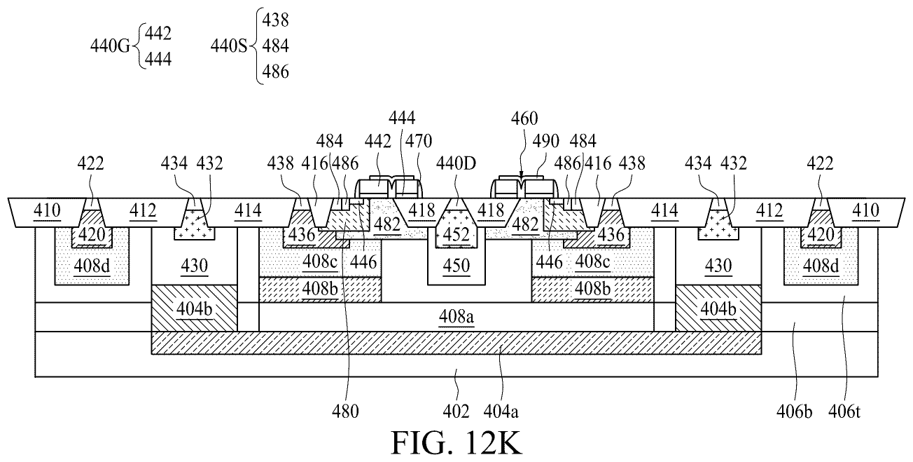

Please refer to FIGS. 12A to 12K, which are schematic drawings illustrating a semiconductor structure at various fabrication stages according to aspects of the present disclosure in one or more embodiments. It should be noted that same elements in FIGS. 4, 5 and FIGS. 12A to 12K may include same materials, and repeated descriptions of such details are omitted for brevity.

Referring to FIG. 12A, in some embodiments, in operation 31, a substrate 402 is received. The substrate 402 may include materials same as those of the substrate 202; therefore, such details are omitted. The substrate 402 may be a semiconductor substrate of a first conductivity type. In some embodiments, operation 31 may include further operations. For example, a buried layer 404a is formed in the substrate 402. The buried layer 404a may include a second conductivity type. The first conductivity type and the second conductivity type are complementary to each other. In some embodiments, the first conductivity type is a p type, and the second conductivity type is an n type. Accordingly, the buried layer 404a may be referred to as a BNBL.

Referring to FIG. 12B, in some embodiments, an epitaxial layer 406b is formed over the substrate 402. The epitaxial layer 406 may be formed by VPE, MBE, ALD or any other suitable method. Referring to FIG. 12C, in some embodiments, another buried layer 404b may be formed in the epitaxial layer 406b. The buried layer 404b may be formed over the buried layer 404a, and coupled to the buried layer 404a. Further, the buried layer 404b may have a ring-shaped or frame-shaped configuration. The buried layer 404b include the second conductivity type, and a dopant concentration of the buried layer 404b may be greater than that of the buried layer 404a. Accordingly, the buried layer 404b may be referred to as an NBL.

Still referring to FIG. 12C, in some embodiments, a deep well region 408a may be formed in the epitaxial layer 406b. The deep well region 408a, and may be referred to as a bottom deep p-well (BDPW). In some embodiments, a bottom of the deep well region 408a is in contact with the buried layer 404a, but the disclosure is not limited thereto. Further, the buried layer 404b laterally surrounds the deep well region 408a. The deep well region 408a is laterally separated from the ring-shaped or frame-shaped buried layer 404b. In some embodiments, the formation of the deep well region 408a may be performed after the formation of the buried layer 404b, but the disclosure is not limited thereto.

In some embodiments, after the forming the buried layer 404b and the deep well region 408a, another epitaxial layer 406t are formed. The epitaxial layer 406t may be formed by VPE, MBE, ALD or any other suitable method. In some embodiments, the epitaxial layer 406b is referred to as a bottom epitaxial layer, while the epitaxial layer 406t is referred to as a top epitaxial layer. In some embodiments, the substrate 402, the buried layers 404a and 404b, and the epitaxial layers 406b and 406t can be referred to as single substrate.

Referring to FIG. 12D, in operation 32, an isolation structure is formed in the substrate 402. In some embodiments, more than one isolation structure can be formed in the substrate 402 and the epitaxial layer 406t. For example, isolation structures 410, 412, 414, 416 and 418 are formed, as shown in FIG. 12D. In some embodiments, an arrangement of the isolation structures 410, 412, 414, 416 and 418 may be similar to that of the isolation structures 210, 212, 214, 216 and 218, but the disclosure is not limited thereto. It should be understood that the arrangement of the isolation structures 410, 412, 414, 416 and 418 can be modified according to various product designs.

Referring to FIG. 12E, in some embodiments, well regions and doped regions may be formed in the substrate 402 and/or the epitaxial layer 406t. For example, well regions 408b, 408c, 408d, 420, 430, 432, 436, 450 and 452, and a doped region 482 are formed. Formations of each of the well regions 408c, 408d, 420, 430, 432, 436, 450 and 452 and the doped region 482 may include forming a patterned photoresist (not shown) over the substrate 402, and performing doping with the patterned photoresist serving as a mask for ion implantation. The patterned photoresist can be removed after the ion implantation or after the respective formation of the well regions 408c, 408d, 420, 430, 432, 436, 450 and 452, and the doped region 482. In some embodiments, a production order of the well regions 408c, 408d, 420, 430, 432, 436, 450 and 452 and the doped region 482 can be: the well regions 430 and 450 are formed, the well region 408c and 480d are then formed, the doped region 482 is then formed, the well region 408b is then formed, the well regions 432 and 452 are then formed, and the well regions 420 and 436 are formed. However, the production order for forming the well regions 408c, 408d, 420, 430, 432, 436, 450 and 452, and the doped region 482 may be modified according to various process designs; therefore, details are omitted for brevity.

In some embodiments, the well regions 408c and 408d may be a well region of the first conductivity type, and thus the well regions 408c and 408d are referred to as HVPWs. The well regions 420 and 436 are well regions of the first conductivity type, and thus the well regions 420 and 436 referred to as an SH_P. In some embodiments, the well regions 430 and 450 are well regions of the second conductivity type, and thus are referred to as HVNWs. In some the well regions 432 and 452 are well regions of the second conductivity type, and thus are referred to as SH_N. The doped region 482 is a region of the second conductivity type, and may be referred to as a high-voltage n-type lightly-doped (HVNDD) region. It should be noted that arrangements of the well regions 408c, 408d, 420, 430, 432, 436, 450 and 452 and the doped region 482 are not limited to those described in the disclosure, and the arrangements may be modified according to various product designs. Additionally, other well regions may be formed according to various product designs; repeated descriptions are omitted for brevity.

In some embodiments, in operation 33, a gate structure is formed over the substrate 402 and the isolation structure 418. In some embodiments, operation 33 includes further operations. For example, referring to FIG. 12F, a dielectric layer 444 and a semiconductor layer 442 are sequentially formed over the substrate 402. A material of the semiconductor layer 442 may be similar to those of the gate conductive layer 142 and 242, and a material of the dielectric layer 444 may be similar to those of the gate dielectric layers 144 and 244; repeated descriptions are omitted for brevity.

Referring to FIG. 12G, the semiconductor layer 442 and the dielectric layer 444 are patterned to form the gate structure 440G. In some embodiments, more than one gate structure 440G may be formed. For example, in some embodiments, two gate structures 440G are formed over the substrate 402. In some embodiments, each of the gate structures 440G overlaps a portion of the well region 482 and a portion of isolation structure 418. Additionally, the two gate structures 440G are formed on two sides of the well region 450.

Referring to FIG. 11, which is a plan view of the gate structure 440G at a fabrication stage according to aspects of the present disclosure in one or more embodiments, in some embodiments a slot 445 is formed in each of the gate structures 440G using a same patterning operation. That is, the gate structures 440G and the slot 445 are simultaneously formed. Parameters, a location and a configuration of the slot 445 may be similar as those of the slot 345; therefore, the repeated descriptions are omitted. In some embodiments, an interface between the isolation structure 418 and the substrate 402 (i.e., the well region 482) is exposed though the slot 445. Further, a sidewall of the semiconductor layer 442 and a sidewall of the dielectric layer 444 are exposed through the respective slot 445. In some embodiments, each of the gate structures 440G has an inner sidewall 448I and an outer sidewall 448O, wherein the inner sidewall 448I is exposed through the respective slot 445.

In some embodiments, more or fewer well regions such as a well region 480 of the first conductivity type may be formed prior to the forming of the gate structure 440G and the slot 445, according to various product designs.

Referring to FIG. 12H, in some embodiments, further operations may be performed. For example, doped region 480 is formed, and then lightly-doped regions 446 may be formed after the formation of the gate structures 440G and the slots 445. In some embodiments, the doped region 480 has the first conductivity type, and thus may be referred to as a high-voltage p-type implanted (HVPB) region. The lightly-doped regions 446 have the second conductive type, and thus are referred to as N-LDDs. As shown in FIG. 12H, the lightly-doped regions 446 may be formed in the HVPB region 480, and abut the outer sidewall 448O of each gate structure 440G. In some embodiments, a bottom and a portion of a sidewall of each lightly-doped region 446 are in contact with the HVPB region 480.

In some embodiments, in operation 34, an insulating structure is formed in the slot 445. In some embodiments, operation 34 includes further operations. For example, an insulating material is formed over the substrate 402. The insulating material may be same as those used to form the abovementioned insulating structures 160/260; therefore, repeated descriptions are omitted. Referring to FIG. 12I, portions of the insulating material are removed to form the insulating structure 460 in each of the gate structures 440G. In some embodiments, the removal of the portions of the insulating material may include etch-back operations, but the disclosure is not limited thereto. As shown in FIG. 12I, the insulating structure 460 is in contact with the inner sidewalls 448I of the respective gate structure 440G. That is, the gate structure 440G laterally surrounds the respective insulating structure 460. The insulating structure 460 overlaps and is in contact with the interface between the isolation structure 418 and the substrate 402 (i.e., the well region 482). In some embodiments, a portion of the insulating structure 460 is formed over the isolation structure 418, and another portion of the insulating structure 460 is formed over the substrate 402 (i.e., the well region 482). In some embodiments, a width of the portion of the insulating structure 460 over the isolation structure 418 is equal to or greater than a width of the portion of the insulating structure 460 over the well region 482, but the disclosure is not limited thereto. Relationships between the isolation structure 418, the well region 482 and the insulating structure 460 may be similar to those described above, and repeated descriptions are omitted.

In some embodiments, a spacer 470 is formed simultaneously with the forming of the insulating structure 460. As shown in FIG. 12I, the spacers 740 are formed over the outer sidewalls 448O of each of the gate structures 440G. The spacers 470 and the insulating structure 460 include same materials.

Referring to FIG. 12J, in operation 35, a source region 440S and a drain region 440D are formed. In some embodiments, when a common-drain approach or a shared-drain approach is adopted, drain region 440D is disposed between the two gate structures 440G, and two source regions 440S are formed. The source regions 440S and the drain region 440D are formed at opposite sides of each gate structure 440G, as shown in FIG. 12J. In some embodiments, the source regions 440S and the drain region 440D have the second conductivity type. A dopant concentration of the drain region 440D is same as dopant concentrations of the source regions 440S. Further, the dopant concentration of the drain region 440D is greater than a dopant concentration of the well region 452.

In some embodiments, other doped regions may be formed prior to or after the forming of the source regions 440S and the drain region 440D. For example, in some embodiments, doped regions 422, 438 and 484 of the first conductivity type may be formed after the forming of the source regions 440S and the drain region 440D, but the disclosure is not limited thereto. In other embodiments, other doped regions may be formed simultaneously with the forming of the source regions 440S and the drain region 440D. For example, a doped region 434 and 486 may be formed simultaneously with the forming of the source regions 440S and the drain region 440D, but the disclosure is not limited thereto. It should be noted that in some embodiments, more or fewer doped regions may be formed according to various product designs.

Referring to FIG. 12K, in some embodiments, after the forming of the doped regions, a dielectric layer 490, such as a RPO layer 490 is formed over each of the insulating structures 460 and a portion of the respective gate structure 440G. In some embodiments, the RPO layer 490 includes a single layer. In other embodiments, the RPO layer 490 includes multiple layers. The RPO layer 490 may be deposited prior to a formation of a silicide structure. A portion of the intermediate device covered by the RPO layer 490 may be protected from siliciding by the RPO layer during such operation.

Accordingly, the present disclosure provides a high-voltage device having an insulating structure disposed within a gate electrode of the high-voltage device. In some embodiments, the insulating structure overlaps an interface between a substrate and an isolation where the gate electrode is disposed. Accordingly, an electric field near the interface, where a gate dielectric layer has less thickness than in other areas, is reduced. Further, an area of maximum electric field is moved away from the interface. Accordingly, a reliability issue can be mitigated. In some embodiments, this is accomplished by adding the insulating structure into the gate structure without modifying operations and/or parameters for forming other elements of the high-voltage device, thereby providing a compatible method for forming the high-voltage device.

According to one embodiment of the present disclosure, a high-voltage device is provided. The high-voltage device includes a substrate, an isolation structure disposed in the substrate, a gate structure disposed over the substrate and the isolation structure, an insulating structure disposed in the gate structure, a drain region disposed on a first side of the gate structure, and source region disposed on a second side of the gate structure. The insulating structure overlaps an interface between the substrate and the isolation structure.

According to one embodiment of the present disclosure, a method for forming a high-voltage device is provided. The method includes following operations. An isolation structure is formed in a substrate. A gate structure is formed over the substrate and the isolation structure. The gate structure includes a slot exposing an interface between the isolation structure and the substrate. An insulating structure is formed in the slot. A source region and a drain region are formed in the substrate.

According to one embodiment of the present disclosure, a method for forming a high-voltage device is provided. The method includes following operations. A substrate is received. The substrate includes an isolation structure formed therein. A dielectric layer and a semiconductor layer are formed over the substrate and the isolation structure. The semiconductor layer and the dielectric layer are patterned to form a gate structure over the substrate and the isolation structure, and to form a slot in the gate structure. The gate structure has an inner sidewall and an outer sidewall. An insulating structure and a spacer are formed. The insulating structure is coupled to the inner sidewall of the gate structure, and the spacer is coupled to the outer sidewall of the gate structure. The insulating structure overlaps an interface between the isolation structure and the substrate. A drain region and a source region are formed in the substrate. The drain region is formed on a first side of the gate structure, and the source region is formed on a second side of the gate structure opposite to the first side.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A high-voltage device comprising:
a substrate;
an isolation structure disposed in the substrate a gate structure disposed over the substrate and the isolation structure;
an insulating structure disposed in the gate structure, wherein the insulating structure overlaps an interface between the substrate and the isolation structure;
a drain region disposed on a first side of the gate structure; and
a source region disposed on a second side of the gate structure.

2. The high-voltage device of claim 1, wherein the insulating structure comprises a first portion over the isolation structure and a second portion over the substrate.

3. The high-voltage device of claim 2, wherein a width of the first portion is equal to or greater than a width of the second portion.

4. The high-voltage device of claim 1, wherein a thickness of the insulating structure is equal to or less than a thickness of the gate structure.

5. The high-voltage device of claim 1, wherein the insulating structure is in contact with the interface between the substrate and the isolation structure.

6. The high-voltage device of claim 1, wherein the gate structure comprises an inner sidewall and an outer sidewall, and the inner sidewall laterally surrounds the insulating structure.

7. The high-voltage device of claim 6, further comprising a spacer disposed over the outer sidewall of the gate structure.

8. The high-voltage device of claim 7, wherein the spacer and the insulating structure comprise a same material.

9. The high-voltage device of claim 1, wherein an extending direction of the insulating structure and an extending direction of the gate structure are parallel.

10. A method for forming a high-voltage device, comprising:
forming an isolation structure in a substrate;
forming a gate structure over the substrate and the isolation structure, wherein the gate structure comprises a slot exposing an interface between the isolation structure and the substrate;
forming an insulating structure in the slot; and
forming a source region and a drain region in the substrate.

11. The method of claim 10, wherein the forming of the gate structure comprises:
forming a dielectric layer over the substrate and the isolation structure;
forming a semiconductor layer over the dielectric layer; and
patterning the semiconductor layer and the dielectric layer to form the gate structure and the slot.

12. The method of claim 10, wherein the forming of the insulating structure comprises:
forming an insulating material over the substrate, wherein the slot is filled with the insulating material; and
removing portions of the insulating material to form the insulating structure.

13. The method of claim 10, further comprising forming a spacer simultaneously with the forming of the insulating structure.

14. The method of claim 10, further comprising forming a buried doped layer prior to the forming of the isolation structure.

15. The method of claim 10, further comprising:
forming a first well region in the substrate; and
forming a second well region in the substrate and separated from the first well region,
wherein the first well region comprises a first conductivity type, and the second well region comprises a second conductivity type complementary to the first conductivity type.

16. The method of claim 15, wherein the first well region is surrounded by the isolation structure, and the second well region surrounds the isolation structure.

17. A method for forming a high-voltage device, comprising:
receiving a substrate comprising an isolation structure formed therein;
forming a dielectric layer and a semiconductor layer over the substrate and the isolation structure;
patterning the semiconductor layer and the dielectric layer to form a gate structure over the substrate and the isolation structure, and to form a slot in the gate structure, wherein the gate structure comprises an inner sidewall and an outer sidewall;
forming an insulating structure coupled to the inner sidewall of the gate structure and a spacer coupled to the outer sidewall of the gate structure, wherein the insulating structure overlaps an interface between the isolation structure and the substrate; and
forming a drain region and a source region in the substrate, wherein the drain region is formed on a first side of the gate structure, and the source region is formed on a second side of the gate structure opposite to the first side.

18. The method of claim 17, wherein the gate structure laterally surrounds the insulating structure.

19. The method of claim 17, wherein the insulating structure comprises a first portion over the isolation structure and a second portion over the substrate, and a width of the first portion is equal to or greater than a width of the second portion.

20. The method of claim 17, further comprising forming a resist protection oxide (RPO) dielectric layer over the insulating structure and a portion of the gate structure.
